(19) United States
(12) Patent Application Publication
(10) Pub. No.: US 2012/0015463 A1
(43) Pub. Date: Jan. 19, 2012

(54) METHOD FOR MANUFACTURING LIGHT-EMITTING DEVICE

(75) Inventors: Yasunari OYABU, Osaka (JP); Hisataka ITO, Osaka (JP); Satoshi SATO, Osaka (JP)

(73) Assignee: NITTO DENKO CORPORATION, Osaka (JP)

(21) Appl. No.: 13/182,814

(22) Filed: Jul. 14, 2011

(30) Foreign Application Priority Data
Jul. 16, 2010 (JP) 2010-161621

(51) Int. Cl. H01L 33/08

(52) U.S. Cl. 438/27; 257/E33.059

(57) ABSTRACT

The present invention relates to a method for manufacturing a light-emitting device, the method including applying resin encapsulation to a lead frame having mounted and packaged thereon a plurality of light-emitting elements, in which the following lead frame portion (A) is used as the lead frame portion: (A) a lead frame portion that is obtained by cutting and separating a lead frame, in which the lead frame has a lattice form including a plurality of rows and a plurality of columns with a plurality of intersection points formed thereby and has a plurality of light-emitting elements disposed and packaged between the adjacent intersection points in each row, into individual column to produce a lead frame portion for each column, and that is passed a light emission test performed by flowing a current to the lead frame portion.

### FIELD OF THE INVENTION

The present invention relates to a method for manufacturing a light-emitting device using a light-emitting element such as LED.

### BACKGROUND OF THE INVENTION

Conventionally, for energy saving of devices, a planar light-emitting device (backlight) using a light-emitting element such as light-emitting diode (hereinafter referred to as “LED”) has been employed as a light source of a liquid crystal display panel such as liquid crystal TV, liquid crystal display and liquid crystal monitor.

As for the light-emitting element substrate such as LED substrate used for the planar light-emitting device, a large number of light-emitting elements (LED elements) are disposed in an array on a planar substrate and after electrically connecting (packaging) these light-emitting elements by wire bonding or the like, each light-emitting element is encapsulated with a resin to complete packaging on a substrate-by-substrate basis. In the case of manufacturing a large light-emitting device, a plurality of light-emitting element substrates each packaged as above are arranged in rows and columns and connected to meet the requirement (see, Patent Documents 1 and 2).

Meanwhile, in the above-described manufacturing method of a light-emitting device, it is known that light output varies according to the height (thickness) or the like of respective light-emitting elements directly packaged on the light-emitting element substrate. Therefore, the light-emitting element substrate used for a light-emitting device is judged as passed or failed through a total inspection whether the light emitting state (e.g., luminance, color temperature) is within the criteria for judgment on variation by performing a light emission test after the packaging above.

Patent Document 1: JP-A-10-144963

Patent Document 2: JP-A-10-294498

### SUMMARY OF THE INVENTION

However, in the above-described manufacturing method of a light-emitting device, the light-emitting element substrate failed the test is wasted on a package-by-package basis, and this disadvantageously leads to a high loss of employed materials and man-hours. Therefore, improvement thereof is demanded.

The present invention has been made under these circumstances, and an object of the present invention is to provide a manufacturing method of a light-emitting device, where materials used such as light-emitting element and substrate are less wasted.

Namely, the present invention relates to the following items (1) to (3).

(1) A method for manufacturing a light-emitting device, the method including applying resin encapsulation to a lead frame having mounted and packaged thereon a plurality of light-emitting elements,

in which the following lead frame portion (A) is used as the lead frame:

(A) a lead frame portion that is obtained by cutting and separating a lead frame,
in which the lead frame has a lattice form including a plurality of rows and a plurality of columns with a plurality of intersection points formed thereby and has a plurality of light-emitting elements disposed and packaged between the adjacent intersection points in each row,
   into individual column to produce a lead frame portion for each column, and that is passed a light emission test performed by flowing a current to the lead frame portion.

(2) The method for manufacturing a light-emitting device according to (1), in which the lead frame portion has a reflector member reflecting light from the light-emitting element.

(3) The method for manufacturing a light-emitting device according to (1), in which, with respect to a lead frame portion that is failed the light emission test, a non-defective light-emitting element in the lead frame portion is separated by cutting and reused.

That is, as a result of continued intensive and extensive investigations to attain the object above, the present inventors have conceived of an idea of using the lead frame having a lattice form including a plurality of rows and a plurality of columns with a plurality of intersection points formed thereby and having a plurality of light-emitting elements disposed and packaged between the adjacent intersection points in each row, cutting and separating the lead frame into individual column to produce a nearly strip-like lead frame portion for each column, and performing a light emission test on a column-by-column basis. The tests were repeated and when a light emission test of the light-emitting element was performed on the lead frame portion basis by applying a current to the lead frame portion cut and separated column by column, it actually became possible to eliminate waste materials and realize enhanced productivity of the light-emitting device. The present invention has been accomplished based on this idea.

On a lead frame portion (A) for use in the light-emitting device of the present invention, respective light-emitting elements packaged on the lead frame portion are electrically connected with each other in parallel when cut and separated into individual column. Therefore, a plurality of light-emitting elements packaged on the lead frame portion can be caused to emit light at the same time by applying a current to the lead frame portion (A), so that a test can be performed on the basis of a lead frame portion cut and separated column by column and the lead frame portion that is passed the test are allowed to be used. As a result, conventional waste materials can be eliminated and resource saving can be realized. The lead frame portion (A) that is passed the above-described light emission test can be directly used in this form for secondary packaging on a substrate of the light-emitting device.

In the case where the lead frame portion has a reflector member which reflects light of the light-emitting element, the reflector member acts to collect light of the light-emitting elements and therefore, luminescence efficiency of light in the lead frame portion s more enhanced.

Also, when a lead frame portion that is failed the light emission test is cut and separated on each light-emitting element basis, and non-defective light-emitting elements in the light-emitting elements are reused, light-emitting elements that is passed the test as well as materials, man-hours and the like spent for the production thereof are not wasted and productivity of the light-emitting device is more enhanced.

### BRIEF DESCRIPTION OF THE DRAWINGS

FIGS. 1A to 1E are views for explaining the outline of the production method of the lead frame used for the light-emitting device in the embodiment of the present invention.

FIG. 2 is a plan view showing the profile of the lead frame used for the light-emitting device in the embodiment of the present invention.

FIGS. 3A to 3E are schematic cross-sectional views for explaining the production method of the lead frame used for the light-emitting device in the embodiment of the present invention.

FIG. 4 shows an example where the lead frame in the embodiment of the present invention is packaged on a backlight substrate of a display.

FIG. 5 shows an example where the lead frame in the embodiment of the present invention is packaged on an LED bulb substrate.

### DETAILED DESCRIPTION OF THE INVENTION

The mode for carrying out the present invention is described in detail below.

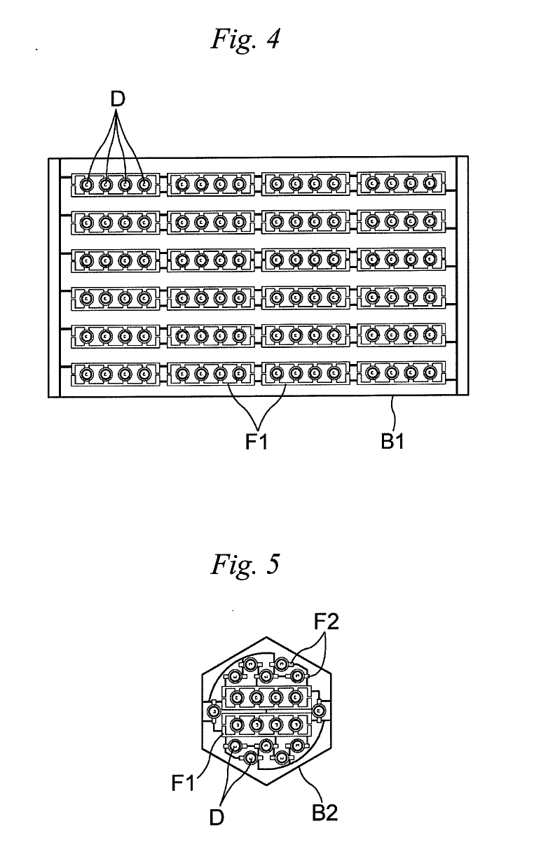

The light-emitting device in this embodiment has a configuration where, for example, as in the backlight substrate B1 for a display shown in FIG. 4 or the LED bulb substrate B2 shown in FIG. 5, lead frames for packaging, such as multichip-type lead frame F1 with a plurality of light-emitting elements (LED, denoted by D) or discrete-type lead frame F2 (usually with a single light-emitting element) individualized by cutting and separating the multichip-type lead frame on an emitter-by-emitter basis, are mounted in juxtaposition with each other on the above-described substrate for packaging (B1, B2) and these lead frames are electrically connected (secondary packaging) with wiring (thick solid line) on the substrate for packaging.

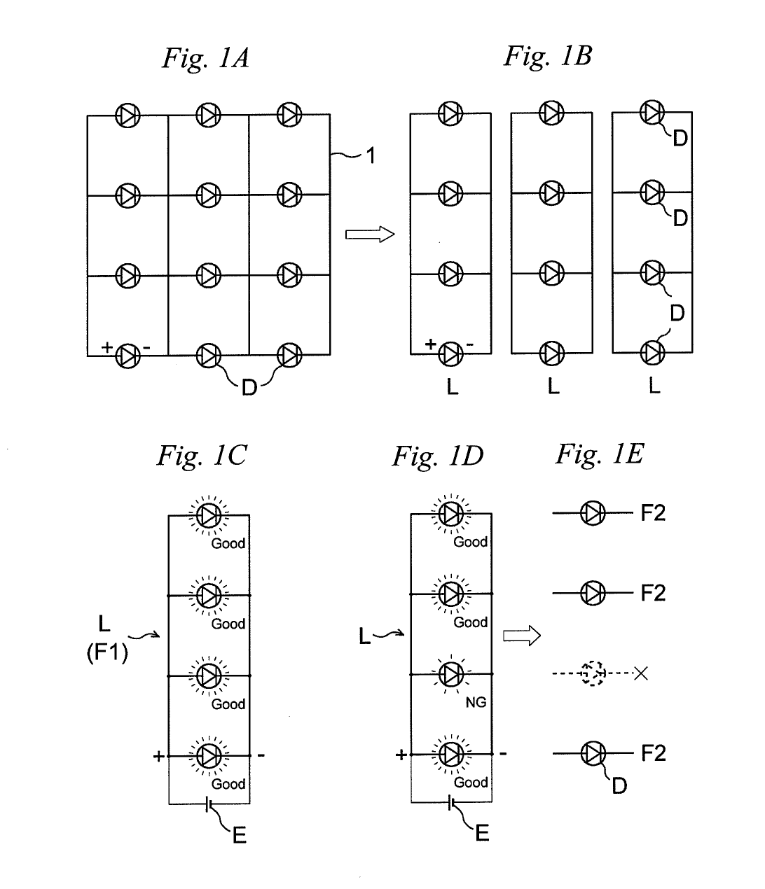

The lead frame for packaging (F1, F2) mounted in the light-emitting device is described in detail below. FIGS. 1A to 1E are circuit diagrams for explaining the outline of the production method of a lead frame used for the light-emitting device in the embodiment of the present invention. In the figures, symbol D indicates LED put into a state capable of emitting light by packaging.

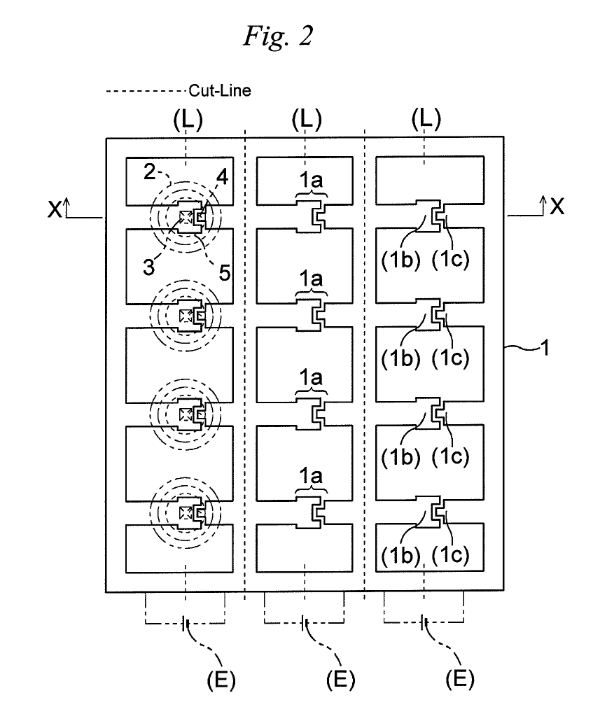

As for the lead frame used in this embodiment, first, as shown in FIG. 1A, LED elements are disposed at predetermined positions (respective electrode sites) of a lead frame 1 (see, FIG. 2) having a grid pattern consisting of rows and columns and are electrically connected (packaged) by wire bonding or the like. At this time, the orientation when packaging each LED element (current flow direction) is “back-to-back arrangement” where all LED elements face in the same direction. In the figures, symbols “+” and “−” denote the positive electrode terminal and the negative electrode terminal of the LED (D).

Next, as shown in FIG. 1B, the lead frame 1 is cut and separated into individual column (longitudinal column) to produce a lead frame portion L where a plurality of (in this example, four) LEDs (D) are disposed in a column (single column). At this time, cutting of the lead frame 1 is performed such that respective LEDs (D) on the lead frame portion L are kept in a state of being electrically connected in parallel.

Subsequently, a light emission test is performed using the lead frame portion L cut and separated column by column. The light emission test is performed, as shown in FIG. 1C, by connecting the positive electrode of a power source E to the positive-side power-supply lead frame joined to the + side terminal of each LED (D) and at the same time, connecting the negative electrode of the power source E to the negative-side power-supply lead frame joined to the − side terminal of each LED (D), thereby lighting respective LEDs (D) all together. Lead frame portion L that is passed the light emission test (inspection) is usually encapsulated with a resin, mounted in juxtaposition on the above-described substrate for packaging of the light-emitting device and electrically connected (secondary packaging) to fabricate the light-emitting device (see, FIGS. 4 and 5).

On the other hand, as shown in FIG. 1D, in a lead frame portion L rejected for the failure in meeting the criteria at the stage of the light emission test above, individual LEDs (D) are measured for luminance, color temperature and the like, and the results are recorded. Thereafter, as shown in FIG. 1E, the lead frame portion L is cut at the pillar part connecting respective LEDs (D) in a column, thereby producing discrete-type lead frames F2 with individual LEDs (D) that are electrically independent from each other, and only a lead frame F2 where the light emission state of LED (D) meets the criteria above is collected and reused as a part of the light-emitting device or for other applications. A lead frame (F2) where the light emission state does not meet the criteria is discarded as a defective product, or a part of the members thereof are utilized as a material.

As described above, the lead frame portion L used for the light-emitting device in this embodiment allows the light emission test of LED (D) to be quickly and swiftly performed on the lead frame portion basis. This eliminates a problem that, as in conventional methods, a light emission test is performed after incorporating and packaging all light-emitting elements and when one light-emitting element is defective, the entirety is judged as failed. That is, the light emission test is performed at a stage prior to completion of a finished product and therefore, even if a defective element is found, the trouble can be overcome merely by excluding it, so that resource saving and energy saving can be realized.

The lead frame F1 that is passed the light emission test can be directly used for secondary packaging on a substrate for packaging of the light-emitting device, so that the lead frame F1 can enhance the productivity of the light-emitting device. Furthermore, according to the lead frame 1, a lead frame portion L that is failed the light emission test can be cut and separated on an emitter-by-emitter basis and non-defective products (F2) out of the emitters can be utilized for packaging of the light-emitting device. Therefore, the lead frame portion L can prevent wasting of LED elements, other members, man-hours and the like spent for the production thereof and can reduce the cost of the light-emitting element package.

The embodiment is more specifically described below by referring to the drawings.

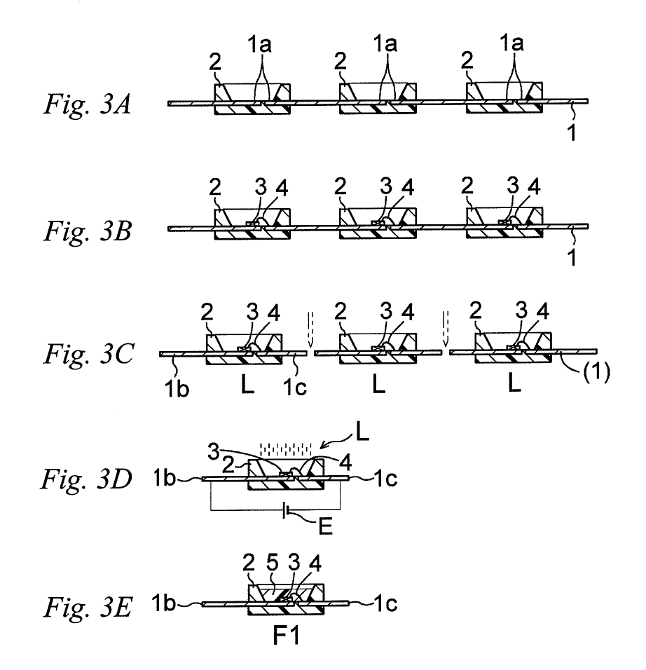

FIG. 2 is a view showing the profile of the lead frame used for the light-emitting device of this embodiment, and FIGS. 3A to 3E are views for explaining, in order of steps, the production method of the lead frame. Incidentally, FIGS. 3A to 3E are cross-sectional views along line X-X in FIG. 2. In the Figures, numeral 1 indicates a lead frame, 2 indicates a reflector member, 3 indicates an LED element, 4 indicates a wire, 5 indicates an encapsulating resin, and the triple circle of two-dot chain line (virtual line) indicates a predetermined position for the formation of these members.

The lead frame 1 used for packaging of the light-emitting element of this embodiment is formed from a metal-made thin plate (electrically conductive material) by a punching method, an etching method or the like. This lead frame has a profile that, as shown in the plan view of FIG. 2, a plurality of columns (in this example, three columns in the transverse direction) each having a column of electrode parts 1a (in this example, four electrode parts in the longitudinal direction) supported by a pillar frame are formed within a frame (outer frame) supporting the entirety of the lead frame.

Respective electrode parts 1a are the positions to mount bare chips of the later-described light-emitting element (LED element) and are designed in “back-to-back arrangement” where the positive electrode side (1b) and the negative electrode side (1c) of each electrode part 1a face in the same direction to align the mounting orientation (directionality) of the LED elements 3. Incidentally, the chain line in FIG. 2 indicates a cut line to cut and separate the lead frame later. When the lead frame is cut and separated by each of these chain lines, as described above in FIG. 1B, three lead frame portions L (three columns) each having a longitudinal column (single column) of four LED elements 3 supported in a state of being electrically connected in parallel are produced (see, the leftmost longitudinal column in FIG. 2).

Production of a lead frame portion L by using such a lead frame 1 is performed as follows. First, as shown in FIG. 3A, a reflector member 2 including an insulating resin is formed in the periphery of each electrode part 1a of the lead frame 1 by using a transfer molding machine or the like. The recess part of the reflector member 2 works out to an LED element 3-housing part and a reflection part and at the same time, fulfills a role as a dam, a dike or the like to prevent the outflow of an encapsulating resin 5.

Subsequently, as shown in FIG. 3B, each LED element 3 is bonded (die-bonded) on the electrode part 1a by using an electrically conductive paste or the like, and the LED elements 3 are electrically connected (packaged) through a wire 4 such as gold wire by using a wire bonding machine.

Thereafter, as shown in FIG. 3C, the lead frame 1 is cut and separated at predetermined positions by a dicing method or the like (see, FIG. 2), whereby three lead frame portions L (three columns) each supporting a column (single column) of four LED elements 3 are produced. Incidentally, as described above, cutting of the lead frame 1 is performed such that respective LED elements 3 on the lead frame portion L are kept in a state of being electrically connected in parallel.

As shown in FIG. 3D, a power source E is then connected to the produced lead frame portion L to perform a light emission test. The light emission test is performed by connecting the positive electrode of the power source E to the positive-side power-supply lead frame 1b joined to the + side terminal of each LED element 3 and at the same time, connecting the negative electrode of the power source E to the negative-side power-supply lead frame 1c joined to the − side terminal of each LED element 3, thereby lighting respective LED elements 3 all together.

Measurement of light emitted from the lead frame portion L is performed on the lead frame portion L basis. In the measurement, for example, a spectrophotometer using a photodiode, CCD, C-MOS or the like, an actinometer, a photometer, a spectral analyzer, or an image sensor can be employed. Also, since light emitted from a plurality of LED elements 3 is measured, a diffuser plate or the like may be disposed between the probe of the optical measuring instrument above and the lead frame portion L. The judgment of pass or fail is performed by deciding whether or not the light quality (luminance), color temperature (wavelength) and the like fall within the predetermined criteria. Only a lead frame portion L that is passed the light emission test is allowed to proceed to the next step.

Next, in the lead frame portion L that is passed the light emission test, as shown in FIG. 3E, a predetermined amount of an encapsulating resin 5 is dropped (potting) on each LED element 3 (in a space of the recess part surrounded by the reflector member 2) and cured by radiation irradiation, heating or the like to effect encapsulating, whereby a lead frame F1 as a product for packaging is completed. This lead frame F1 is then mounted in juxtaposition on the substrate for packaging of the above-described light-emitting device and electrically connected (secondary packaging) to fabricate the light-emitting device (see, FIGS. 4 and 5). Incidentally, in this embodiment, resin encapsulation to the lead frame portion L is performed after the light emission test. However, the resin encapsulation may be performed before the light emission test of the lead frame portion L.

Other than mounting on the substrate for packaging, the lead frame F1 that is passed the light emission test can be also used directly as a unit of a light-emitting element module by itself or by connecting the lead frames F1.

In this way, when the lead frame F1 of this embodiment is used, variation of light emission thereof can be known before mounting the lead frame on the substrate for packaging of the light-emitting device, so that waste of materials used, such as substrate for packaging, light-emitting element and encapsulating resin, can be reduced. Also, the light emission test is performed on the basis of a lead frame portion cut and separated column by column and therefore, this test can be swiftly performed.

Similarly to the previous embodiment, the lead frame portion L which rejected for the failure in meeting the criteria at the stage of the light emission test is cut by a dicing apparatus or the like at the pillar part connecting respective LED elements 3 in a column of the frame, thereby producing discrete-type lead frames F2 with individual LED elements 3 independent from each other, and only a lead frame F2 where the light emission state of the LED element 3 meets the criteria can be used as a part of the light-emitting device or for other applications.

As for the material constituting the reflector member 2, an insulating thermoplastic resin or thermosetting resin can be used. Above all, a silicone resin excellent in the heat resistance is preferred, and a thermosetting addition-reactive silicone resin having a structure where either a vinyl group or an allyl group and a hydrogen atom are bonded directly to a silicon atom, is more preferred. The resin constituting the reflector 2 contains a white pigment (e.g., titanium oxide) for increasing the light reflectance.

The encapsulating resin for encapsulating the light-emitting element includes, for example, an epoxy or silicone resin having light transparency. Such an encapsulating resin may contain a fluorescent material or the like.

The light-emitting element used is preferably an LED element, more preferably a blue LED or an ultraviolet LED, where white color or visible light can be obtained through wavelength conversion by the fluorescent material above.

### EXAMPLES

Working examples are described below, but the present invention is not limited to the following Examples.

### Example 1

A copper-made plate material with the surface being plated with silver was punched into a predetermined shape (see, FIG. 2), thereby preparing a lead frame, and a bare chip of blue LED (SL-V-B15AA, manufactured by SEMILEDS) was die-bonded to each electrode part (a longitudinal column of four electrode parts×three columns in the transverse direction) of the prepared lead frame by using a silver paste. Thereafter, the chips were packaged by wire bonding using a gold wire, and the lead frame was cut at the position of Cut-Line shown in FIG. 2 to produce a lead frame portion L for light emission test.

Subsequently, while a positive electrode was connected to the positive-side power-supply lead frame of the lead frame portion L, the negative electrode of the power source was connected to the negative-side power-supply lead frame and in a state of lighting each blue LED, the emission wavelength was measured using a spectrophotometer (MCPD-7000, manufactured by Otsuka Electronics Co., Ltd.). The acceptance criterion in the test was the reference wavelength±10 nm.

Thereafter, a silicone elastomer (LR7665, produced by Wacker Asahikasei Silicone Co., Ltd.) was dropped in the electrode part (on the blue LED) of the lead frame portion L that is passed the test and cured to encapsulate the blue LED. In this way, the lead frame of Example 1 was obtained.

### Example 2

The lead frame of Example 2 was obtained in the same manner as in Example 1 except that before the bare chip of the blue LED was packaged, a white reflector was previously formed by transfer molding.

The transfer molding of the white reflector was performed using a resin composition containing the following components (i) to (iii):

(i) a thermosetting addition-reactive silicone resin having a structure where either a vinyl group or an allyl group and a hydrogen atom are bonded directly to a silicon atom,

(ii) a platinum-based catalyst as a curing catalyst for the component (i), and

(iii) a white pigment.

In a light-emitting device using the lead frame obtained in Example 1 or 2, a failure (a failure ascribable to the LED element) after secondary packaging was not generated, and the productivity of the light-emitting device could be enhanced.

While the invention has been described in detail with reference to specific embodiments thereof, it will be apparent to one skilled in the art that various changes and modifications can be made therein without departing from the spirit and scope thereof.

Incidentally, the present application is based on Japanese Patent Application No. 2010-161621 filed on Jul. 16, 2010, and the contents are incorporated herein by reference.

All references cited herein are incorporated by reference herein in their entirety.

Also, all the references cited herein are incorporated as a whole.

The present invention is suitable for a light-emitting device such as backlight or LED bulb using an emitter (e.g., LED), where light-emitting elements packaged on a lead frame are secondarily packaged on a device substrate.

### DESCRIPTION OF REFERENCE NUMERALS AND SIGNS

1 Lead frame
D LED
L Lead frame portion
F1, F2 Lead frame

What is claimed is:

1. A method for manufacturing a light-emitting device, said method comprising applying resin encapsulation to a lead frame having mounted and packaged thereon a plurality of light-emitting elements,
wherein the following lead frame portion (A) is used as the lead frame:
(A) a lead frame portion that is obtained by cutting and separating a lead frame,
wherein said lead frame has a lattice form comprising a plurality of rows and a plurality of columns with a plurality of intersection points formed thereby and has a plurality of light-emitting elements disposed and packaged between the adjacent intersection points in each row,
into individual column to produce a lead frame portion for each column, and that is passed a light emission test performed by flowing a current to the lead frame portion.

2. The method for manufacturing a light-emitting device according to claim 1, wherein the lead frame portion has a reflector member reflecting light from the light-emitting element.

3. The method for manufacturing a light-emitting device according to claim 1, wherein, with respect to a lead frame portion that is failed the light emission test, a non-defective light-emitting element in the lead frame portion is separated by cutting and reused.
